(19) United States
(12) Patent Application Publication
(10) Pub. No.: US 2024/0397793 A1
(43) Pub. Date: Nov. 28, 2024

(54) DISPLAY DEVICE AND METHOD OF MANUFACTURING THE SAME

(71) Applicants: SAMSUNG DISPLAY CO., LTD., YONGIN-SI (KR); Se Gyung Hi Tech Co., LTD, Suwon-si (KR)

(72) Inventors: YOUNGSANG PARK, Yongin-si (KR); IN JU KIM, Asan-si (KR); UI JONG YU, Incheon (KR); SUNG JIN KIM, Hwaseong-si (KR); MINSEOK DO, Yongin-si (KR); MINSEONG BYEON, Yongin-si (KR); SUNGGUK AN, Yongin-si (KR); CHUL HO JEONG, Yongin-si (KR)

(21) Appl. No.: 18/648,614

(22) Filed: Apr. 29, 2024

(30) Foreign Application Priority Data
May 26, 2023 (KR) 10-2023-0068432

(51) Int. Cl. H10K 59/80; H10K 59/12; H10K 59/126

(52) U.S. Cl. CPC H10K 59/873; H10K 59/1201; H10K 59/126

(57) ABSTRACT

A display device includes a display panel including a display area and a non-display area adjacent to the display area, an impact resistance layer disposed in the display area and the non-display area on the display panel and including a polymer material, a protective film disposed on the impact resistance layer and a light-blocking layer disposed in the non-display area between the impact resistance layer and the protective film.

### CROSS-REFERENCE TO RELATED APPLICATION(S)

This application claims priority under 35 U.S.C. § 119 and all the benefits accruing therefrom to Korean Patent Application No. 10-2023-0068432, filed on May 26, 2023, in the Korean Intellectual Property Office, the contents of which is hereby incorporated by reference herein for all purposes in its entirety.

### BACKGROUND

### 1. FIELD

Embodiments relate to a display device and a method of manufacturing the same. More particularly, embodiments provide a display device that presents visual information and a method of manufacturing the same.

### 2. DESCRIPTION OF THE RELATED ART

A display device is a device that may display an image for providing visual information to a user. Display devices may include a liquid crystal display (LCD), a plasma display panel (PDP), and an organic light emitting display (OLED).

Display devices may include a protective film and a display panel. The protective film may be on the display panel and protect the display panel. The protective film may provide high impact resistance against impacts applied from the inside or outside.

### SUMMARY

Embodiments provide a display device with improved impact resistance.

Embodiments provide a method of manufacturing a display device with improved impact resistance.

A display device according to an embodiment of the present disclosure may include a display panel including a display area and a non-display area adjacent to the display area, an impact resistance layer in the display area and the non-display area of the display panel, wherein the impact resistance layer includes a polymer material, a protective film on the impact resistance layer, and a light-blocking layer in the non-display area between the impact resistance layer and the protective film.

In an embodiment, the impact resistance layer may directly contact the light-blocking layer and the protective film.

In an embodiment, the polymer material may include a soft material including at least one polymer material selected from a group consisting of thermoplastic polyurethane (TPU), polyether block amide (PEBA), silicon acrylate, and polyurethane.

In an embodiment, the polymer material may include the soft material and an adhesive material.

In an embodiment, the adhesive material may include a pressure sensitive adhesive (PSA).

In an embodiment, the impact resistance layer may include a first impact resistance layer on a surface of each of the light-blocking layer and the protective film and a second impact resistance layer on the first impact resistance layer.

In an embodiment, the first impact resistance layer may include a pressure sensitive adhesive.

In an embodiment, the second impact resistance layer may include a soft material including at least one polymer material selected from a group consisting thermoplastic polyurethane (TPU), polyether block amide (PEBA), silicone acrylate, and polyurethane.

In an embodiment, the first impact resistance layer may directly contact the light-blocking layer and the protective film.

In an embodiment, the second impact resistance layer may directly contact the first impact resistance layer.

In an embodiment, the display area may include a foldable area having flexibility.

A method of manufacturing a display device according to an embodiment of the present disclosure may include forming a display panel including a display area and a non-display area adjacent to the display area, forming a protective film in the display area and the non-display area, forming a light-blocking area overlapping the non-display area on one surface of the protective film, and forming an impact resistance layer overlapping the display area and the non-display area on a surface of the protective film, wherein the impact resistance layer includes a polymer material.

In an embodiment, the forming of the impact resistance layer may include coating the impact resistance layer directly on a surface of each of the light-blocking layer and the protective film.

In an embodiment, the impact resistance layer may be coated on the light-blocking layer and the protective film by a thermal transfer process.

In an embodiment, the impact resistance layer may include a soft material and an adhesive material.

In an embodiment, the adhesive material may include a pressure sensitive adhesive (PSA).

In an embodiment, the soft material may include at least one polymer material selected from a group consisting of thermoplastic polyurethane (TPU), polyether block amide (PEBA), silicone acrylate, and polyurethane.

In an embodiment, the forming of the impact resistance layer may include forming a first impact resistance layer on one surface of each of the light-blocking layer and the protective film, and forming a second impact resistance layer on the first impact resistance layer.

In an embodiment, the first impact resistance layer may include an adhesive material.

In an embodiment, the second impact resistance layer may include at least one polymer material selected from a group consisting of thermoplastic polyurethane (TPU), polyether block amide (PEBA), silicone acrylate and polyurethane.

In a display device according to embodiments of the present disclosure, the display device may include display panel including a foldable area having flexibility, an impact resistance layer disposed on the display panel and including a polymer material, and light-blocking layer disposed between the impact resistance layer and a protective film. Accordingly, impact resistance of the display device may be improved. In addition, as the display device includes an impact resistance layer, the overall thickness of the display device may increase, thereby improving the durability of the display device.

In the method of manufacturing the display device according to embodiments of the present disclosure, the light-blocking layer may be formed on the protective film, and the impact resistance layer including a polymer material may be formed directly on one surface of the protective film and the light-blocking layer. Accordingly, the manufacturing process of the display device may be simplified.

### BRIEF DESCRIPTION OF THE DRAWINGS

Principles and embodiments of the present disclosure will be more clearly understood from the following detailed description in conjunction with the accompanying drawings.

FIG. 1 is a plan view illustrating a display device, according to an embodiment of the present disclosure.

FIG. 2 is a side view illustrating an example of the display device of FIG. 1 in a folded state.

FIG. 3 is a side view illustrating another example of the display device of FIG. 1 in a folded state.

FIG. 4 is a cross-sectional view taken along line I-I′ of FIG. 1.

FIG. 5 is an enlarged cross-sectional view of are A of FIG. 4.

FIG. 6 is an enlarged cross-sectional view of a display panel of FIG. 4.

FIGS. 7, 8, 9, and 10 are cross-sectional views illustrating a method of manufacturing the display device, according to an embodiment of the present disclosure.

FIG. 11 is a cross-sectional view illustrating another example of an impact resistance layer of FIG. 6.

FIG. 12 is a cross-sectional view illustrating another example of the impact resistance layer of FIG. 6.

### DETAILED DESCRIPTION OF THE EMBODIMENTS

Hereinafter, display devices in accordance with various embodiments will be described in more detail with reference to the accompanying drawings. The same reference numerals are used for the same components in the drawings, and redundant descriptions of the same components may be omitted.

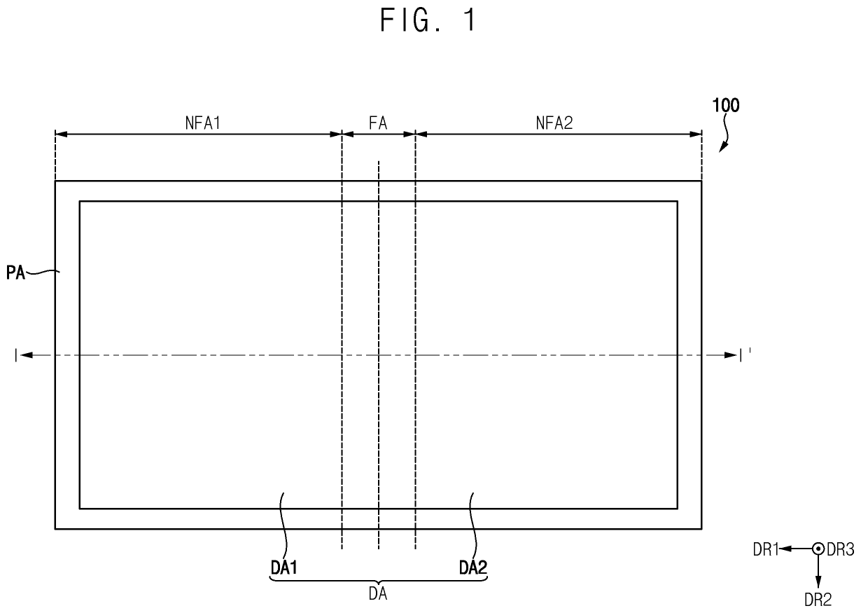

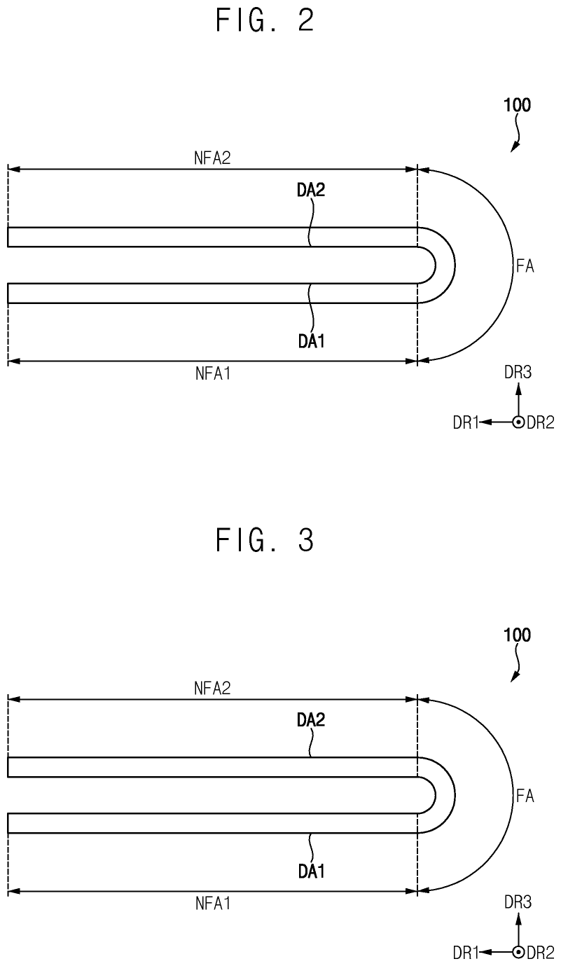

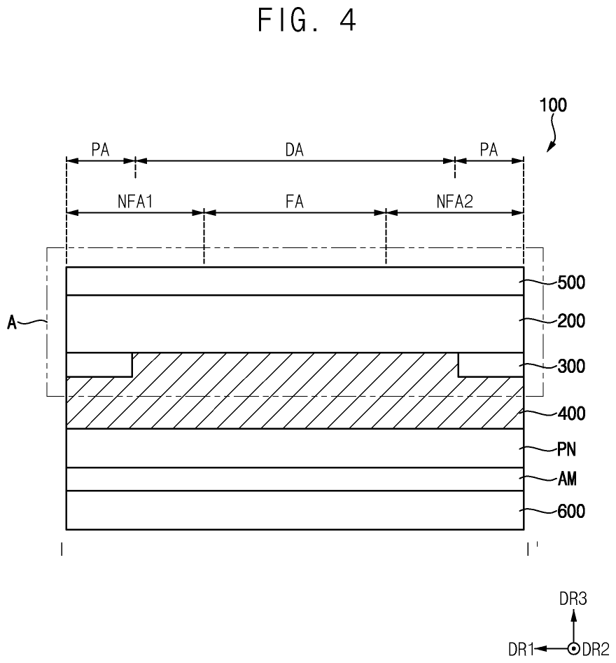

FIG. 1 is a plan view illustrating a display device according to an embodiment of the present disclosure. FIG. 2 is a side view illustrating an example of the display device of FIG. 1 in a folded state. FIG. 3 is a side view illustrating another example of the display device of FIG. 1 in a folded state.

Referring to FIG. 1, FIG. 2 and FIG. 3, a display device 100 may include a display area DA and a non-display area PA, which may be referred to as a peripheral area. The display area DA may be an area that generates an image and the non-display area PA may be an area that does not generate an image. The non-display area PA may be adjoining the display area DA, where for example, the non-display area PA may be a continuous area that entirely surrounds the display area DA (e.g., a boarder).

At least a portion of the display device 100 may be flexible, where the display device 100 may be folded at the flexible portion (i.e., a foldable area FA.). The display area DA may include a first non-folding area NFA1 and a second non-folding area NFA2 on opposites sides of the foldable area FA, where the foldable area FA can be bent by an external force, so that the display device 100 can be folded, such that the first non-folding area NFA1 and the adjacent second non-folding area NFA2 are no longer coplanar. In various embodiments, the foldable area FA is between and separates the first non-folding area NFA1 and the second non-folding area NFA2, where the foldable area FA may have a folding axis extending in a second direction DR2. The foldable area FA and the first and the second non-folding area NFA1 and NFA2 may at least partially overlap the display area DA, where the foldable area FA, first non-folding area NFA1, and second non-folding area NFA2 may include at least a portion of the non-display area PA, respectively. Although an area may be referred to as the non-folding area, this is for convenience of explanation, and therefore the expression “non-folding” may include a display device 100 with areas that are rigid due to lack of material flexibility, and also display device 100 with areas that are flexible, but do not fold because the flexibility is smaller than the foldable area FA.

In various embodiments, the display area DA may be divided along a second direction DR2 that intersects a first direction DR1 into a first display area DA1 and a second display area DA2 adjacent to the first display area DA1. The first direction DR1 may intersect the second direction DR2. The first display area DA1 and the second display area DA2 may be continuously connected to substantially form one display area DA. When the display area DA is folded along the folding axis, the display device 100 may have an in-folding structure, the foldable area FA can be sufficiently flexible that the first display area DA1 and the second display area DA2 can be disposed on the inside surface after folding, and positioned facing each other, as shown in FIG. 2.

In various embodiments, when the display area DA is folded along the folding axis, the display device 100 may have an out-folding structure in which the display area DA is disposed on the outside surface after folding, as shown in FIG. 3.

In various embodiments, the display device 100 may include a plurality of foldable areas FA, where the display device 100 may be folded at multiple locations along the display area DA or may include a sufficient number of foldable areas FA to implement a rollable display device 100.

In FIGS. 1, 2, and 3, the display device 100 is described as including a foldable area (FA), but the embodiments of the present disclosure may not be limited thereto. For example, the display device 100 may be a rigid display device 100 that is rigid and does not bend easily.

In this specification, a plane may be defined in the first direction DR1 and the second direction DR2. For example, the second direction DR2 may be perpendicular to the first direction DR1. In addition, a third direction DR3 may be perpendicular to the plane formed by the intersecting first direction DR1 and second direction DR2.

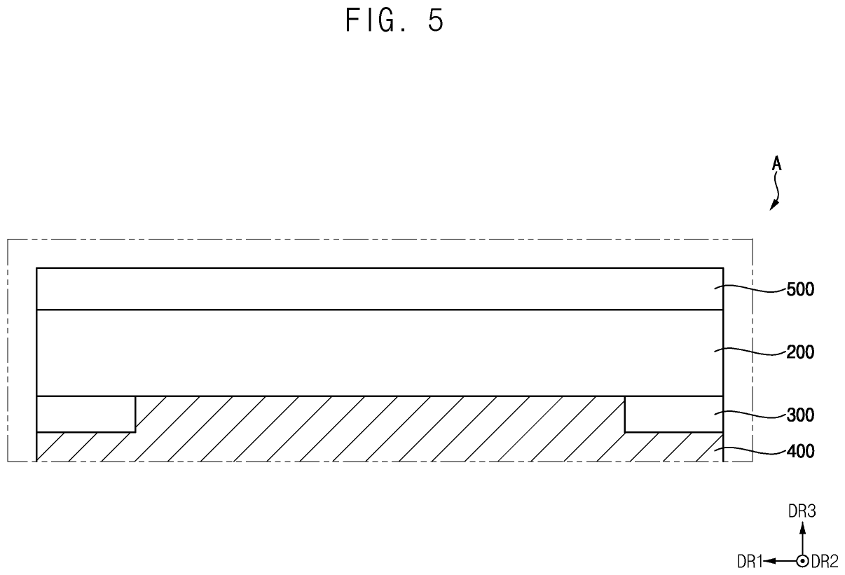

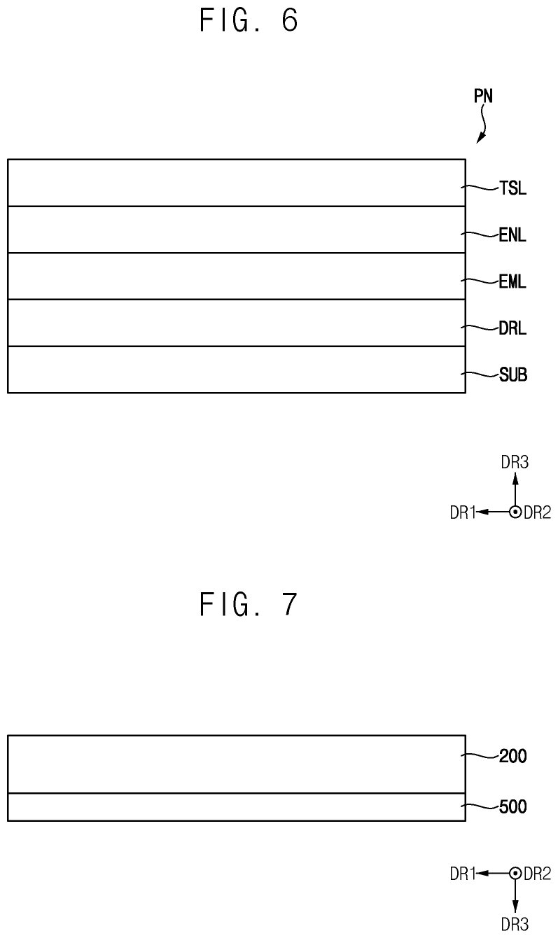

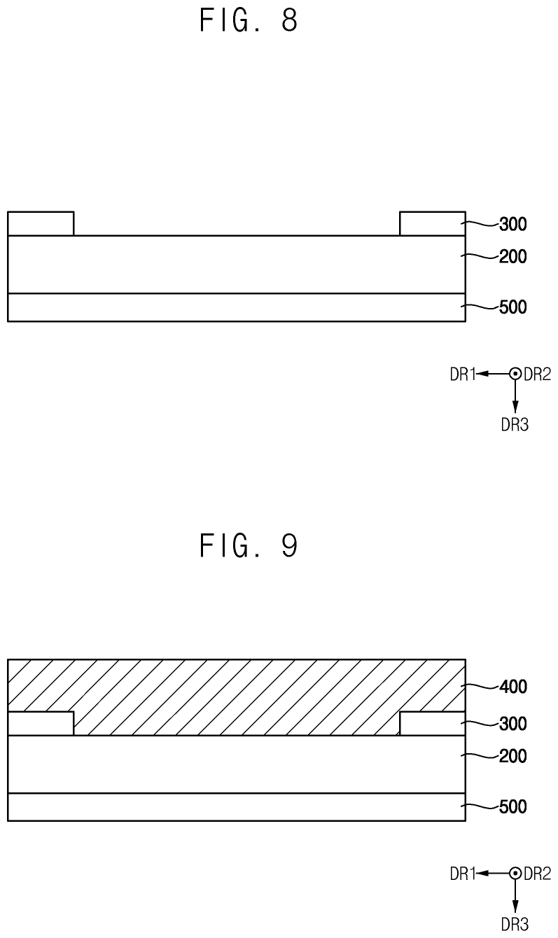

FIG. 4 is a cross-sectional view taken along line I-I′ of FIG. 1. FIG. 5 is an enlarged cross-sectional view of area A of FIG. 4. FIG. 6 is an enlarged cross-sectional view of a display panel of FIG. 4.

Referring to FIG. 4 to FIG. 6, the display device 100 according to an embodiment of the present disclosure may include a coating layer 500, a protective film 200, a light-blocking layer 300, an impact resistance layer 400, a display panel PN, an adhesive member AM, and a support member 600.

Referring to FIG. 4, the first and the second non-folding area NFA1 and NFA2 may be formed longer than the non-display area PA in the first direction DR1.

In various embodiments, the display device 100 includes the display area DA and the non-display area PA, where the display panel PN may be included in the display area DA and the non-display area PA. The display panel PN may include a plurality of sub-pixels configured to generate light.

In various embodiments, the display panel PN may be adjacent to the light-blocking layer 300 in the non-display area PA, where the light-blocking layer 300 can determine the length of the non-display area PA in the first direction DR1. The light-blocking layer 300 may include a material that can block light, where for example, the light-blocking layer 300 may include an inorganic material and/or an organic material containing an organic pigment of a specific color (for example, black).

In various embodiments, the light-blocking layer 300 may block at least some portion of the light emitted from the plurality of sub-pixels disposed under the light-blocking layer 300. In addition, the light-blocking layer 300 may serve to block a view of components placed on an edge of the display panel PN (for example, the non-display area PA) from being viewed from outside. For example, the light-blocking layer 300 may be disposed in the non-display area PA and overlap with wires that transmit various signals and voltages to the sub-pixels.

In various embodiments, the protective film 200 may be disposed on the light blocking layer 300 and the impact resistance layer 400. The protective film 200 may include a glass or a polymer material. The polymer material may include polyimide, polyacrylate, polyehtylene terephtalate (PET), and the like. These may be used alone or in combination with each other.

In various embodiments, the coating layer 500 may be disposed on the protective film 200, where the coating layer 500 may be affixed to an upper surface of the protective film 200 and may serve to protect the protective film 200. In addition, the coating layer 500 may prevent fingerprints and scratches on the protective film 200. For example, the coating layer 500 may include urethane acrylate, acrylic ester, acrylate, epoxy acrylate, and the like. These may be used alone or in combination with each other.

In an embodiment, the impact resistance layer 400 may be between the protective film 200 and the display panel PN, where the impact resistance layer 400 can separate the display panel PN from the protective film 200. The impact resistance layer 400 may include a polymer material. The polymer material may include a soft material, such as thermoplastic polyurethane (TPU), polyether block amide (PEBA), silicone acrylate, polyurethane, and the like.

Referring to FIG. 5, in various embodiments, the impact resistance layer 400 may be disposed on a surface of each of the protective film 200 and the light blocking layer 300. The impact resistance layer 400 may be directly in contact with a surface of the protective film 200 and a surface of the light blocking layer 300. The impact resistance layer 400 may include a recess forming a step to accommodate the light blocking layer 300, where an upper surface of the light blocking layer 300 and an upper surface of at least a portion of the impact resistance layer 400 may be coplanar.

In various embodiments, the impact resistance layer 400 may have high impact resistance against impacts applied from the inside or outside. Accordingly, the impact resistance layer 400 may protect the display panel from impacts applied from the inside or outside.

In various embodiments, the support member 600 may be disposed under the display panel PN, as shown in FIG. 4. The support member 600 may serve to support the display panel PN. The support member 600 may include the foldable area FA of the display device 100, where the foldable area FA may serve to help the display panel PN be folded. For example, the portion where the foldable area FA and the support member 600 overlap may have elasticity in response to the folding and unfolding of the display device 100. In various embodiments, the support member 600 may be a metal with a high thermal conductivity.

In various embodiments, the adhesive member AM may be disposed between the display panel PN and the support member 600. An upper surface of the adhesive member AM may be directly in contact with a lower surface of the display panel PN, and a bottom surface of the adhesive member AM may be directly in contact with an upper surface of the support member 600. Therefore, the adhesive member AM may attach the display panel PN and the support member 600. For example, the adhesive member AM may include optical clear adhesive (OCA), pressure sensitive adhesive (PSA), photocurable resin, thermosetting resin, and the like. These may be used alone or in combination with each other. The adhesive member AM containing an adhesive material may not be disposed between the protective film 200 and the impact resistance layer 400.

Referring to FIG. 6, the display panel PN may include multiple layers, including a substrate SUB, a circuit driving layer DRL disposed on the substrate SUB, a light emitting layer EML disposed on the circuit driving layer DRL, an encapsulation layer ENL disposed on the light emitting layer EML, and a touch layer TSL disposed on the encapsulation layer ENL.

In various embodiments, the substrate SUB may include an insulating material, such as a glass, a quartz, and/or one or more polymers. The substrate SUB may be a rigid substrate or a flexible substrate containing a flexible molecular material such as polyimide (PI). With a flexible substrate, the display panel PN may be bent, folded, or curled.

In various embodiments, the circuit driving layer DRL may be disposed on the substrate SUB, where the circuit driving layer DRL may be between the substrate SUB and a light emitting layer EML. The circuit driving layer DRL may include a pixel circuit driving the light emitting layer EML. For example, the circuit driving layer DRL may include a plurality of thin film transistors.

In various embodiments, the light emitting layer EML may be disposed on the circuit driving layer DRL, where the light emitting layer EML may be between the circuit driving layer DRL and an encapsulation layer ENL. The light emitting layer EML may emit light with various brightness depending on the driving signal transmitted from the circuit driving layer DRL. The light emitting layer EML may include an organic light emitting layer.

In various embodiments, the encapsulation layer ENL may be disposed on the light emitting layer EML, where the encapsulation layer ENL may be between the light emitting layer EML and a touch layer TSL. The encapsulation layer ENL may include an inorganic film or a stacked film of an inorganic film and organic film.

In various embodiments, the touch layer TSL may be disposed on the encapsulation layer ENL. The touch layer TSL may be a layer that recognizes touch pressure and may perform the function of a touch member. The touch layer TSL may include a plurality of sensing areas and a plurality of sensing electrodes that can detect an applied pressure.

### Comparative Examples and Examples

According to Example 1, by attaching the impact resistance layer 400 including polyurethane and having a thickness of 60 μm to the bottom of the protective film 200 including polyethylene terphtalate (PET) and having a thickness of 50 μm, a structure in which the sum of thicknesses of the protective film 200 and the impact resistance layer 400 was 110 μm was manufactured.

According to Example 2, by attaching the impact resistance layer 400 including polyurethane and having a thickness of 90 μm to the bottom of the protective film 200 including polyethylene terphtalate (PET) and having a thickness of 50 μm, a structure in which the sum of thicknesses of the protective film 200 and the impact resistance layer 400 was 140 μm was manufactured.

According to Comparative Example 1, a structure including a protective film including polyethylene terphtalate (PET) and having the thickness of 50 μm was manufactured.

According to Comparative Example 2, a structure including a protective film including polyethylene terphtalate (PET) and having the thickness of 100 μm was manufactured.

TABLE 1

| | Thickness of the | Total thicknesses of |
|---|---|---|
| | protective film (μm) | the structure (μm) |
| Example 1 | 50 | 110 |
| Example 2 | 50 | 140 |
| Comparative Example 1 | 50 | 50 |
| Comparative Example 2 | 100 | 100 |

Table 2 evaluates an impact resistance characteristics of display devices according to Examples and Comparative Examples. Specifically, in order to evaluate the impact resistance characteristics of the display devices according to the Examples and the Comparative Examples, a pen drop test was performed on both Examples 1 and 2, and Comparative Examples 1 and 2.

The pen drop is used to evaluate the impact resistance characteristics and measures the height at which a defect in the display device occurs when the same “pen” is dropped on the display device.

TABLE 2

| | Pen drop (cm) |
|---|---|
| Example 1 | 10.5 |
| Example 2 | 17.5 |
| Comparative Example 1 | 8.5 |
| Comparative Example 2 | 10 |

As a result, it may be confirmed that the structure including the protective film 200 and the impact resistance layer 400 satisfying Example 1 and Example 2 had an improved pen drop height compared to the structure satisfying Comparative Example 1 and Comparative Example 2.

From these results, it may be confirmed that the display device 100 including the impact resistance layer 400 according to an embodiment of the present disclosure has excellent impact resistance characteristics.

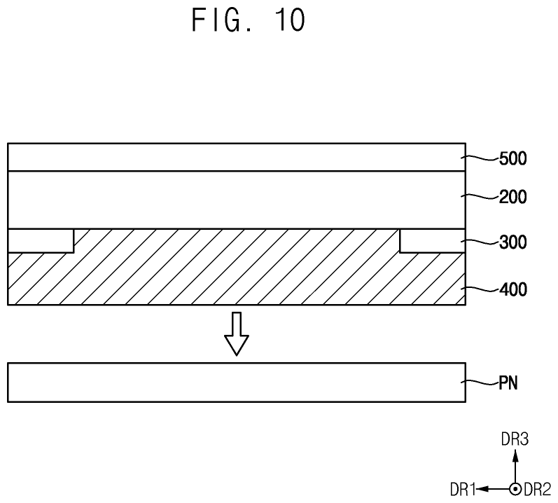

FIGS. 7, 8, 9 and 10 are cross-sectional views of illustrating a method of manufacturing the display device.

Referring to FIG. 7, the coating layer 500 may be formed on the protective film 200. For example, the protective film 200 may be formed by using a material having impact resistance and transparency. In an embodiment, the material having impact resistance and transparency may include a glass or a polymer material. For example, the coating layer 500 may include urethane acrylate, acrylic ester, acrylate, epoxy acrylate, and the like. These may be used alone or in combination with each other.

Referring to FIG. 8, the light blocking layer 300 may be disposed on the protective film 200. The light blocking layer 300 may be formed in the non-display area (for example, the non-display area PA). The light blocking layer 300 may be formed by using an inorganic material and/or an organic material containing an organic pigment of a specific color, for example, black.

In various embodiments, the light blocking layer 300 may be formed by directly coating on one surface of the protective film 200, where the light blocking layer 300 may be formed on the surface opposite the coating layer 500. The light blocking layer 300 may be directly in contact with the protective film 200 in the non-display area. However the light blocking layer 300 may not be limited to being formed by coating directly on one surface of the protective film 200. For example, the light blocking layer 300 may be formed on one surface of the protective film 200 by using an inkjet printing method.

Referring to FIG. 9, the impact resistance layer including a polymer material may be formed on a surface of each of the protective film 200 and the light blocking layer 300. For example, the polymer material may be formed by using a soft material, such as thermoplastic polyurethane (TPU), polyether block amide (PEBA), silicone acrylate, polyurethane, and the like.

In an embodiment, the impact resistance layer 400 may be directly coated on a surface of the protective film 200 and a surface of the light blocking layer 300, where the impact resistance layer 400 may not use an adhesive material (for example, optical clear adhesive, pressure sensitive adhesive, and the like), and may be directly coated on the surfaces of the protective film 200 and the light blocking layer 300. The impact resistance layer 400 may be formed on a top surface and a side surface of the light blocking layer 300 to form a step. A portion of the impact resistance layer 400 may be formed on a top surface of the protective film 200.

In various embodiments, the impact resistance layer 400 may be formed by a thermal transfer process. For example, the thermal transfer process may include a micro dry process decoration (MDD) thermal transfer process. The MDD thermal transfer process may be processed at a pressure ranging from about 150 to 300 kgf/mm² and a temperature of about 80 to 105° C., and a rate of about 0.1 to 0.2 inch/sec by using a thermal transfer head to which voltage of about 200 to 210 V is applied at about 90 to 105 pulses per second (pps). Accordingly, it may be possible to prevent the production of a film with an uneven cross-section due to poor reaction stability.

As a result, the protective film 200 may be formed, the light blocking layer 300 may be formed on the protective film 200, and the impact resistance layer 400 may be directly coated on the one surface of each of the protective film 200 and the light blocking layer 300, where before forming the impact resistance layer 400, the light blocking layer 300 may be formed on the protective film 200.

Referring to FIG. 10, the impact resistance layer 400, the light blocking layer 300, the protective film 200, and the coating layer 500 may be combined with the display panel PN, where the impact resistance layer 400 may be affixed to the display panel PN. The display panel PN may be disposed under the impact resistance layer 400 in the third direction DR3, where the impact resistance layer 400, the light blocking layer 300, the protective film 200, and the coating layer 500 may be flipped, such that a previously upper surface of the impact resistance layer 400 faces the display panel PN. Specifically, the impact resistance layer 400, the protective film 200, and the coating layer 500 may be combined with the display panel PN through an adhesive material, for example, optical clear adhesive, pressure sensitive adhesive, and the like.

Referring to FIG. 4 again, the display panel PN may be combined with the support member 600 through the adhesive member AM, where the adhesive member AM can affix the display panel PN to the support member 600.

Accordingly, the display device 100 of FIG. 4 may be manufactured.

According to the Comparative Examples, when an impact resistance layer 400 is formed on a protective film 200, and a light blocking layer 300 is directly coated on the impact resistance layer 400, the light blocking layer 300 may not be in contact with the impact resistance layer 400 entirely. For example, when the light blocking layer 300 is coated on the impact resistance layer, wrinkles may occur in the light blocking layer, making it difficult for the light blocking layer to entirely contact the impact resistance layer. When the impact resistance layer 400 is formed on the protective film 200, and the light blocking layer 300 is coated on the impact resistance layer 400, a surface treatment, for example, a plasma treatment, may be utilized in order for the light blocking layer to be entirely in contact with the light blocking layer 300.

As shown in FIG. 7 to FIG. 10, in the method of manufacturing the display device 100, according to embodiments of the present disclosure, the light blocking layer 300 may be formed on one surface of the protective film 200, and the impact resistance layer 400 including a polymer material may be directly formed on a surface of each of the protective film 200 and the light blocking layer 300. The impact resistance layer 400 may be formed by coating directly on a surface of each of the protective film 200 and the light blocking layer 300. Accordingly, the surface treatment between the impact resistance layer 400 and the light blocking layer 300 may not be required, so the manufacturing process of the display device 100 may be simplified.

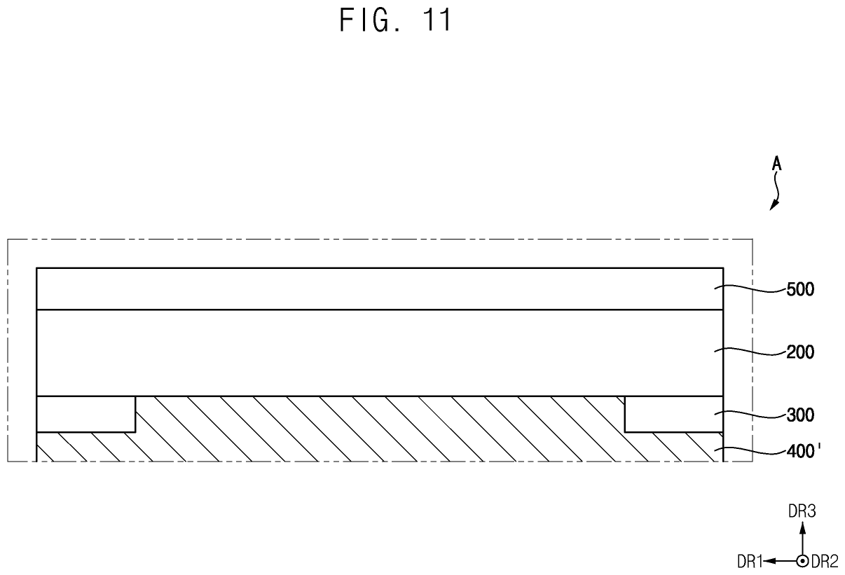

FIG. 11 is a cross-sectional view illustrating another example of an impact resistance layer of FIG. 6.

Referring to FIG. 11, the light blocking layer 300 and the impact resistance layer 400′ may be disposed on one surface of the protective film 200, which may be a lower surface. The impact resistance layer 400′ may include a polymer material, where the polymer material may include a soft material and an adhesive material.

In various embodiments, the polymer material may include a pressure sensitive adhesive, an optical sensitive adhesive, and the like. These may be used alone or in combination with each other.

In various embodiments, the soft material may include thermoplastic polyurethane (TPU), polyether block amide (PEBA), silicone acrylate, polyurethane, and the like. These may be used alone or in combination with each other.

In an embodiment, the impact resistance layer 400′ may be formed by attaching the adhesive material to one surface of each of the protective film 200 and the light blocking layer 300 and then mixing the soft material with the adhesive material.

In another embodiment, after mixing the adhesive material with the soft material, an impact resistance layer 400′ including the adhesive material and the soft material may be formed on one surface of each of the protective film 200 and the light blocking layer 300.

In various embodiments, the impact resistance layer 400′, including the adhesive material, may be formed on a surface of each of the protective film 200 and the light blocking layer 300 by a laminating process. However, the embodiments of the present closure may not limited thereto. The impact resistance layer 400′, including the adhesive material, may be formed on a surface of each of the protective film 200 and the light blocking layer 300 by various processes.

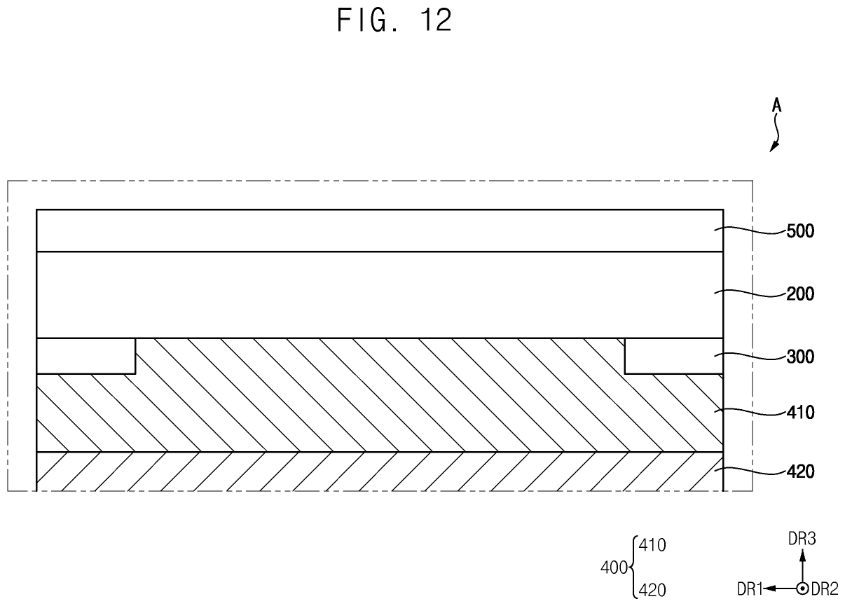

FIG. 12 is a cross-sectional view illustrating another example of the impact resistance layer of FIG. 6.

Hereinafter, descriptions that overlap with the components of the display device 100 described with reference to FIGS. 4 and 5 may be omitted or simplified.

Referring to FIG. 12, the impact resistance layer 400 may include a first impact resistance layer 410 and a second impact resistance layer 420. For example, the impact resistance layer 400 may include the first impact resistance layer 410 disposed on a surface of each of the protective film 200 and the light blocking layer 300, and the second resistance layer 420 on a bottom surface of the first resistance layer 410.

In an embodiment, the first impact resistance layer 410 may be directly in contact with the protective film 200 and the light blocking layer 300. In addition, the second impact resistance layer 420 may be directly in contact with the first impact resistance layer 410. For example, the second resistance layer 420 may be formed by directly coating on the first impact resistance layer 410.

In an embodiment, the first impact resistance layer 410 may include an adhesive material. The adhesive material may include a pressure sensitive adhesive, an optical sensitive adhesive, and the like. These may be used alone or in combination each other.

In an embodiment, the second impact resistance layer 420 may include TPU (thermoplastic polyurethane), polyether block amide (PEBA), silicone acrylate, polyurethane, and the like. These may be used alone or in combination each other.

In various embodiments, the first impact resistance layer 410 may be formed on a surface of each of the protective film 200 and the light blocking layer 300, and the second impact resistance layer 420 may be formed on the bottom of the first impact resistance layer 410. Accordingly, the impact resistance layer 400 including the first impact resistance layer 410 and the second impact resistance layer 420 may be formed.

In various embodiments, the second impact resistance layer 420 may be formed on the bottom of the first impact resistance layer 410, where the impact resistance layer 400 including the first impact resistance layer 410 and the second impact resistance layer 420 may be formed on a surface of each of the protective film 200 and the light blocking layer 300.

For example, the first impact resistance layer 410 may be formed on a surface of each of the protective film 200 and the light blocking layer 300 by laminating process. However, the embodiments of the present disclosure may not be limited to thereto, the first impact resistance layer 410 including the adhesive material may be formed on the surfaces of each of the protective film 200 and the light blocking layer 300 by various processes.

The display device and the method of manufacturing the same according to the embodiments may be applied to a display device included in a computer, a notebook, a mobile phone, a smartphone, a smart pad, a PMP, a PDA, an MP3 player, or the like.

Although the methods and the systems according to the embodiments have been described with reference to the drawings, the illustrated embodiments are non-limiting examples, and may be modified and changed by a person having ordinary knowledge in the relevant technical field without departing from the scope and technical spirit of the following claims.

What is claimed is:

1. A display device comprising:
a display panel including a display area and a non-display area adjacent to the display area;
an impact resistance layer in the display area and the non-display area of the display panel, wherein the impact resistance layer includes a polymer material;
a protective film on the impact resistance layer; and
a light-blocking layer in the non-display area between the impact resistance layer and the protective film.

2. The display device of claim 1, wherein the impact resistance layer directly contacts the light-blocking layer and the protective film.

3. The display device of claim 1, wherein the polymer material includes a soft material, wherein the soft material is selected from the group consisting of thermoplastic polyurethane (TPU), polyether block amide (PEBA), silicon acrylate, and polyurethane.

4. The display device of claim 3, wherein the polymer material includes the soft material and an adhesive material.

5. The display device of claim 4, wherein the adhesive material includes a pressure sensitive adhesive (PSA).

6. The display device of claim 1, wherein the impact resistance layer includes:
a first impact resistance layer on a surface of each of the light-blocking layer and the protective film; and
a second impact resistance layer on the first impact resistance layer.

7. The display device of claim 6, wherein the first impact resistance layer includes a pressure sensitive adhesive.

8. The display device of claim 6, wherein the second impact resistance layer includes a soft material, where the soft material is selected from the group consisting of thermoplastic polyurethane (TPU), polyether block amide (PEBA), silicone acrylate, and polyurethane.

9. The display device of claim 7, wherein the first impact resistance layer directly contacts the light-blocking layer and the protective film.

10. The display device of claim 6, where in the second impact resistance layer directly contacts the first impact resistance layer.

11. The display device of claim 1, wherein the display area includes a foldable area having flexibility.

12. A method of manufacturing a display device, the method comprising:
forming a display panel including a display area and a non-display area adjacent to the display area;
forming a protective film in the display area and the non-display area;
forming a light-blocking area overlapping the non-display area on one surface of the protective film; and
forming an impact resistance layer overlapping the display area and the non-display area on a surface of the protective film, wherein the impact resistance layer includes a polymer material.

13. The method of claim 12, wherein the forming of the impact resistance layer includes coating the impact resistance layer directly on a surface of each of the light-blocking layer and the protective film.

14. The method of claim 13, wherein the impact resistance layer is coated by a thermal transfer process.

15. The method of claim 12, wherein the impact resistance layer includes a soft material and an adhesive material.

16. The method of claim 15, wherein the adhesive material includes a pressure sensitive adhesive (PSA).

17. The method of claim 15, wherein the soft material is selected from the group consisting of thermoplastic polyurethane (TPU), polyether block amide (PEBA), silicone acrylate, and polyurethane.

18. The method of claim 13, wherein the forming of the impact resistance layer includes:
forming a first impact resistance layer on a surface of each of the light-blocking layer and the protective film; and
forming a second impact resistance layer on the first impact resistance layer.

19. The method of claim 18, wherein the first impact resistance layer includes an adhesive material.

20. The method of claim 18, wherein the second impact resistance layer is selected from the group consisting of thermoplastic polyurethane (TPU), polyether block amide (PEBA), silicone acrylate, and polyurethane.
